(19) United States
(12) Patent Application Publication
(10) Pub. No.: US 2025/0137129 A1
(43) Pub. Date: May 1, 2025

(54) DEPOSITION APPARATUS

(71) Applicant: Samsung Display Co., Ltd., Yongin-si (KR)

(72) Inventors: CHOELMIN JANG, Yongin-si (KR); JUNGGON KIM, Yongin-si (KR); MYUNGSOO HUH, Yongin-si (KR)

(73) Assignee: Samsung Display Co., Ltd., Yongin-si (KR)

(21) Appl. No.: 18/826,577

(22) Filed: Sep. 6, 2024

(30) Foreign Application Priority Data
Nov. 1, 2023 (KR) 10-2023-0148899

(51) Int. Cl. C23C 16/455

(52) U.S. Cl. CPC C23C 16/45565

(57) ABSTRACT

A deposition apparatus including a deposition chamber having an inner space that accommodates a substrate and provides a vacuum or non-vacuum state to the substrate, the inner space defined by a floor surface, a ceiling surface and a wall surface, a gas spraying part that is accommodated in the inner space, includes a lower surface facing the substrate and an upper surface, and sprays gas onto the substrate, and a substrate conveying part accommodated in the inner space, having the substrate disposed thereon, and moving the substrate in the first direction. A thickness of the gas spraying part varies along the second direction, and in the non-vacuum state, the lower surface of the gas spraying part has a curved surface, and in the vacuum state, the lower surface of the gas spraying part has a flat surface on a plane defined by the first direction and the second direction.

### CROSS-REFERENCE TO RELATED APPLICATIONS

This U.S. non-provisional patent application claims priority to and benefit of Korean Patent Application No. 10-2023-0148899 under 35 U.S.C. § 119, filed on Nov. 1, 2023, the disclosure of which is hereby incorporated by reference in its entirety.

### BACKGROUND

### 1. Technical Field

The disclosure herein relates to a deposition apparatus, and more particularly, to a deposition apparatus with which thickness uniformity of a deposition target is maintained substantially constant.

### 2. Description of the Related Art

A display device, such as a television, a monitor, a smartphone, and a tablet computer that provide images to a user, includes a display panel that displays images. Various display panels such as a liquid crystal display panel, an organic light emitting display panel, an electrowetting display panel, and an electrophoretic display panel are being developed as display panels.

For manufacture of a display device, a chemical vapor deposition (CVD) process and an atomic layer deposition (ALD) process, through which a thin film (deposition target) is deposited by spraying gas onto a surface of a target substrate, and a plasma enhanced chemical vapor deposition (PECVD) process and a plasma enhanced atomic layer deposition (PEALD) process, through which deposition is performed in a plasma state by applying a high voltage while spraying a process gas, are used. As a size of a substrate on which a deposition target is deposited becomes larger, a size of a gas spraying part for spraying gas also becomes larger, thereby leading to a decrease in uniformity of a thin film thickness, which is undesirable.

### SUMMARY

The disclosure provides a deposition apparatus capable of easily controlling gas flow between a gas spraying part and a substrate.

The disclosure also provides a deposition apparatus that allows plasma to have a uniform density according to a position between a gas spraying part and a substrate.

An embodiment provides a deposition apparatus that includes: a deposition chamber including an inner space that accommodates a substrate and provides a vacuum state or a non-vacuum state to the substrate, the inner space being defined by a floor surface defined by a first direction and a second direction crossing each other, a ceiling surface opposed to the floor surface, and a wall surface connecting the floor surface and the ceiling surface; a gas spraying part that is accommodated in the inner space, and which includes a lower surface facing the substrate and an upper surface opposed to the lower surface, and which sprays gas onto the substrate; and a substrate conveying part accommodated in the inner space, having the substrate disposed thereon, and which moves the substrate in the first direction, wherein a thickness of the gas spraying part varies along the second direction, and in the non-vacuum state, the lower surface of the gas spraying part has a curved surface, and in the vacuum state, the lower surface of the gas spraying part has a flat surface on a plane defined by the first direction and the second direction.

In an embodiment, in the non-vacuum state, the upper surface of the gas spraying part may have a flat surface defined by the first direction and the second direction, and in the vacuum state, the upper surface of the gas spraying part may have a curved surface.

In an embodiment, in the non-vacuum state, the lower surface may be a recessed surface with respect to the substrate.

In an embodiment, the gas spraying part may have a first thickness at a center portion of the gas spraying part, and respectively have a second thickness and a third thickness at one side portion and the other side portion of the gas spraying part, and the second thickness and the third thickness may be symmetrical with respect to the center portion of the gas spraying part.

In an embodiment, a difference between the second thickness and the first thickness may be a value in a range from about 0.1 mm to about 1 mm.

In an embodiment, in the non-vacuum state, a first gap defined as a distance between the center portion of the lower surface and the substrate may be greater than a second gap and a third gap defined as distances between the substrate and one side and the other side portions of the lower surface.

In an embodiment, the second gap and the third gap may be symmetrical with respect to the center portion of the lower surface.

In an embodiment, the second gap and the third gap may be each a value in a range from about 0.3 mm to about 2 mm, and a difference between the second gap and the first gap may be a value in a range from about 0.1 mm to about 1 mm.

In an embodiment, the second gap and the third gap may be each a value in a range from about 0.6 mm to about 1 mm.

In an embodiment, the gas spraying part may have a length of a value in the range from about 2400 mm or more in the second direction.

In an embodiment, the gas spraying part may be provided in plurality, and the plurality of gas spraying parts may include a first gas spraying part that sprays first gas, and a second gas spraying part that sprays second gas different from the first gas.

In an embodiment, the deposition chamber further may include a support part that supports the gas spraying part.

In an embodiment, a deposition apparatus includes a deposition chamber including an inner space that accommodates a substrate and provides a vacuum state or a non-vacuum state to the substrate, the inner space being defined by a floor surface defined by a first direction and a second direction crossing each other, a ceiling surface opposed to the floor surface, and a wall surface connecting the floor surface and the ceiling surface; a gas spraying part that is accommodated in the inner space, which includes a lower surface facing the substrate and an upper surface opposed to the lower surface, and sprays gas onto the substrate; and a substrate conveying part accommodated in the inner space, having the substrate disposed thereon, and which moves the substrate in the first direction, wherein the gas spraying part is disposed along the second direction crossing the first direction, and includes a first portion and a second portion connected to each other with a center portion thereof as a boundary, in the non-vacuum state, a first gap defined as a distance between the center portion and the substrate is greater than a second gap defined as a distance between the first portion and the substrate, and in the vacuum state, the first gap may be same as the second gap.

In an embodiment, in the non-vacuum state, a third gap defined by a distance between the second portion and the substrate may be smaller than the first gap, and the second gap and the third gap may be symmetrical with respect to the center portion.

In an embodiment, the deposition chamber further may include a support part which supports the gas spraying part.

In an embodiment, the center portion may have a first thickness between the lower surface and the upper surface, the first portion may have a second thickness greater than the first thickness between the lower surface and the upper surface, the second portion may have a third thickness greater than the first thickness between the lower surface and the upper surface, and the second thickness and the third thickness may be symmetrical with respect to the center portion.

In an embodiment, the first gap may be a value in the range from about 0.3 mm to about 2 mm, and a difference between the second gap and the first gap may be a value in the range from about 0.1 mm to about 1 mm.

In an embodiment, a difference between the second thickness and the first thickness may be a value in the range from about 0.1 mm to about 1 mm.

In an embodiment, an upper surface of the substrate conveying part may be a recessed surface with respect to the substrate.

In an embodiment, the substrate conveying part may include: a first support portion overlapping the first portion; and a second support portion overlapping the second portion, the first support portion and the second support portion connected to each other with a center portion, of the substrate conveying part, corresponding to the center portion of the gas spraying part as a boundary, and the first support portion and the second support portion may become further recessed as being closer to the center portion of the substrate conveying part.

### BRIEF DESCRIPTION OF THE DRAWINGS

The accompanying drawings are included to provide a further understanding of the inventive concept, and are incorporated in and constitute a part of this specification. In the drawings, the sizes, thicknesses, ratios, and dimensions of the elements may be exaggerated for ease of description and for clarity. Like reference numbers and/or like reference characters refer to like elements throughout. The drawings illustrate embodiments of the inventive concept and, together with the description, serve to explain principles of the inventive concept. In the drawings:

FIG. 1A is a combined perspective view of a display device according to an embodiment that is constructed according to principles of the disclosure;

FIG. 1B is an exploded perspective view of a display device according to an embodiment;

FIG. 2 is a cross-sectional view of a display device according to an embodiment;

FIG. 3 is a plan view of a display panel according to an embodiment;

FIG. 4A is a front view schematically illustrating a deposition apparatus according to an embodiment;

FIG. 4B is a perspective view of a part of a deposition apparatus according to an embodiment;

FIG. 4C is a cross-sectional view schematically illustrating a deposition apparatus according to an embodiment;

FIG. 4D is a cross-sectional view schematically illustrating a deposition apparatus according to an embodiment;

FIG. 5A is a cross-sectional view illustrating a deposition apparatus, in a non-vacuum state, according to an embodiment;

FIG. 5B is a cross-sectional view illustrating a deposition apparatus, in a vacuum state, according to an embodiment;

FIG. 5C is a cross-sectional view of a deposition apparatus according to an embodiment;

FIG. 6A is a perspective view of a part of a deposition apparatus according to an embodiment; and

FIG. 6B is a cross-sectional view illustrating a deposition apparatus, in a vacuum state, according to an embodiment.

### DETAILED DESCRIPTION OF THE EMBODIMENTS

In this specification, it will be understood that when an element (or region, layer, portion, or the like) is referred to as being “on”, “connected to” or “coupled to” another element, it may be directly disposed/connected/coupled to another element, or intervening elements may be disposed therebetween.

Like reference numerals or symbols refer to like elements throughout. Also, in the drawings, the thickness, the ratio, and the dimension of the elements are exaggerated for effective description of the technical contents. The term “and/or” includes all of one or more combinations defined by the associated elements.

Although the terms first, second, etc., may be used to describe various elements, these elements should not be limited by these terms. These terms are only used to distinguish one element from another element. For example, a first element may be referred to as a second element, and similarly, a second element may also be referred to as a first element without departing from the scope of the inventive concept. The singular forms include the plural forms as well, unless the context clearly indicates otherwise.

Also, the terms such as “below”, “lower”, “above”, “upper” and the like, may be used for the description to describe one element's relationship to another element illustrated in the figures. It will be understood that the terms have a relative concept and are described on the basis of the orientation depicted in the figures.

It will be understood that the term “includes” or “comprises”, when used in this specification, specifies the presence of stated features, integers, steps, operations, elements, components, or a combination thereof, but does not preclude the presence or addition of one or more other features, integers, steps, operations, elements, components, or combinations thereof.

Unless otherwise defined, all terms (including technical and scientific terms) used herein have the same meaning as commonly understood by one of ordinary skill in the art to which the present disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing illustrative features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the illustrative term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some illustrative embodiments may be physically separated into two or more interacting and discrete blocks, units, and/or modules without departing from the scope of the inventive concepts. Further, the blocks, units, and/or modules of some illustrative embodiments may be physically combined into more complex blocks, units, and/or modules without departing from the scope of the inventive concepts.

Hereinafter, a display panel according to an embodiment and a method for manufacturing the same will be described with reference to the accompanying drawings.

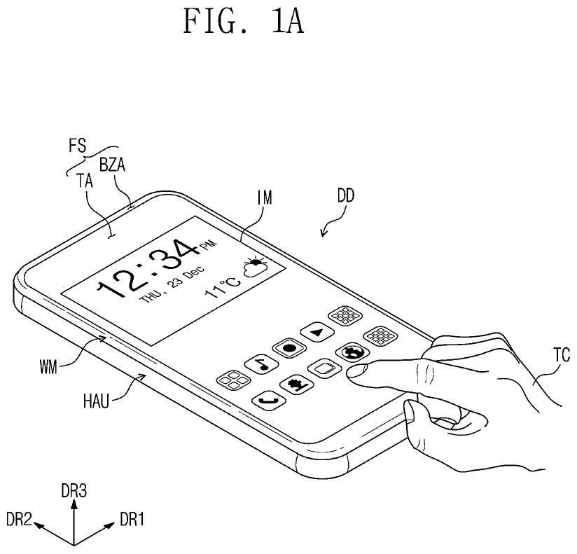

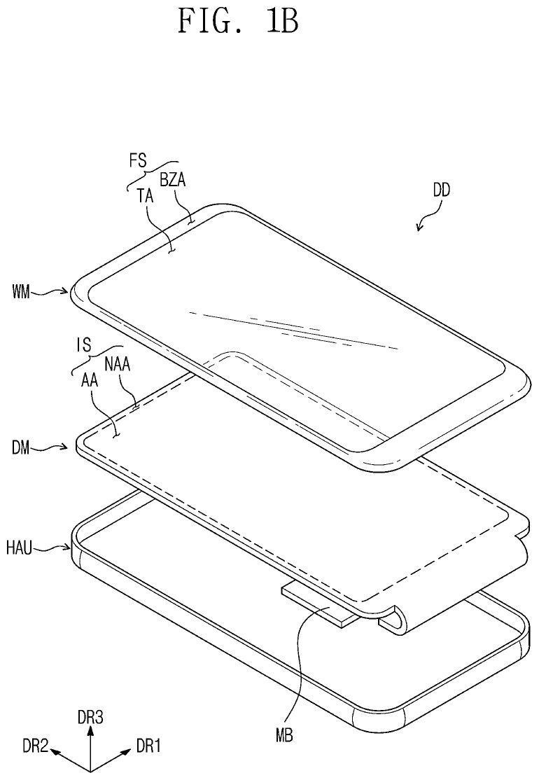

FIG. 1A is a combined perspective view of a display device according to an embodiment that is constructed according to principles of the disclosure, and FIG. 1B is an exploded perspective view of a display device according to an embodiment.

Referring to FIGS. 1A and 1B, a display device DD may be activated in response to an electrical signal. The display device DD may display an image IM and detect an external input TC (shown in FIG. 1A as being provided by a user's finger to the display device DD). The display device DD may include various embodiments. For example, the display device DD may include a tablet computer, a laptop computer, a desktop computer, a smart television, and the like. In this embodiment, the display device DD is illustrated as a smart phone.

The display device DD may display an image IM, in a third direction DR3, on a display surface FS parallel to each of a first direction DR1 and a second direction DR2. The display surface FS on which the image IM is displayed may correspond to a front surface of the display device DD and a front surface FS of a window member WM. Hereinafter, the same reference numerals or symbols are used for a display surface and a front surface of the display device DD, and a front surface of the window member WM. The image IM may include not only a dynamic image but also a static image. In FIG. 1A, a clock display and application icons are illustrated as the images IM.

In this embodiment, a front surface (or upper surface) and a rear surface (or lower surface) of each member are defined based on a direction in which the image IM is displayed. The front surface and the rear surface may be opposed to each other in the third direction DR3, and a normal (i.e., perpendicular) direction of each of the front surface and the rear surface may be parallel to the third direction DR3. A spacing distance between the front surface and the rear surface in the third direction DR3 may correspond to a thickness of the display panel DP in the third direction DR3. The directions indicated by the first to third directions DR1 to DR3 may have a relative concept, and may thus be changed to other directions.

The display device DD according to an embodiment may detect a user's input TC applied from the outside (i.e., external to the display device DD). The user's input TC includes various types of external inputs such as a part of a user's body, light, heat, pen, or pressure. In this embodiment, the user's input TC is illustrated as a finger of a user's hand that is applied to the front surface. However, this is illustrated as one of many possible ways to provide an external input to the display device DD, and as described above, the user's input TC may be provided in various forms. The display device DD may detect the user's input TC that is applied to a side surface or a rear surface of the display device DD according to a configuration of the display device DD, and is not limited to any one embodiment.

As illustrated in FIGS. 1A and 1B, the display device DD includes a window member WM, a display module DM, and an external case HAU. In this embodiment, the window member WM and the external case HAU are coupled to constitute the exterior of the display device DD. In this embodiment, the external case HAU, the display module DM, and the window member WM may be sequentially stacked along the third direction DR3.

The window member WM may include an insulating panel. For example, the window member WM may be composed of glass, plastic, or a combination thereof.

As described above, the front surface FS of the window member WM defines the front surface of the display device DD. A transmission region TA may be an optically transparent region. For example, the transmission region TA may be a region having a visible light transmittance of about 90% or more.

A bezel region BZA may be a region having a relatively lower light transmittance than the transmission region TA. The bezel region BZA defines a shape of the transmission region TA. The bezel region BZA may be adjacent to the transmission region TA and surround the transmission region TA.

The bezel region BZA may have a predetermined color. The bezel region BZA may cover a peripheral region NAA of the display module DM to block the peripheral region NAA from being viewed from the outside. This is exemplarily illustrated in FIG. 1B, and in the window member WM according to an embodiment, the bezel region BZA may be omitted in other possible implementations of this embodiment.

The display module DM may display the image IM and detect the external input TC. The image IM may be displayed on a front surface IS of the display module DM. The front surface IS of the display device DM includes an active region AA and the peripheral region NAA. The active region AA may be activated in response to an electrical signal.

In this embodiment, the active region AA may be not only a region in which the image IM is displayed, but also a region in which the external input TC is detected. The transmission region TA overlaps at least the active region AA. For example, the transmission region TA overlaps the front surface or at least a portion of the active region AA. Accordingly, a user may view the image IM through the transmission region TA or provide the external input TC, as is illustrated in FIG. 1A. In the active region AA, a region, in which the image IM is displayed, and a region, in which the external input TC is detected, may be separated from each other, whereby the disclosure is not limited to any one embodiment.

The peripheral region NAA may be covered by the bezel region BZA. The peripheral region NAA is adjacent to the active region AA. The peripheral region NAA may surround the active region AA. A driving circuit, a driving wire, or the like for driving the active region AA may be disposed in the peripheral region NAA.

The display module DM may include a display panel and an input-sensing unit. The image IM may be substantially displayed on the display panel, and the external input TC may be substantially detected by the input-sensing unit. The display module DM includes both the display panel and the input-sensing unit, and thus display the image IM and also detect the external input TC. The detailed description thereof will be described later.

At least a portion of the display module DM may be bent. In this embodiment, since a portion, of the display module DM, connected to a circuit board MB is bent toward the rear surface of the display module DM, the circuit board MB may be assembled to overlap the rear surface of the display module DM.

The display device DD may further include a circuit board MB connected to the display module DM. The circuit board MB is coupled to one side of the display module DM and thus physically and electrically connected to the display module DM. The circuit board MB may generate an electrical signal provided to the display module DM, or receive the signal generated from the display module DM, and may calculate a resultant value including information about a position at which the external input TC is detected, or about a strength of the detected external input TC.

The external case HAU and the window member WM are coupled to form the exterior of the display device DD. The external case HAU provides a predetermined inner space. The display module DM may be accommodated in the inner space.

The external case HAU may include a material having relatively high rigidity. For example, the external case HAU may include glass, plastic, or metal or include a plurality of frames and/or plates composed of combinations thereof. The external case HAU may stably protect components, of the display device DD, accommodated in the inner space against an external impact.

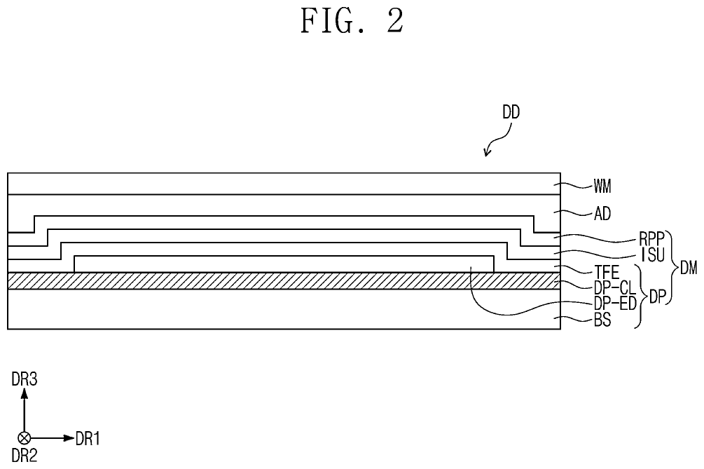

FIG. 2 is a cross-sectional view of a display device according to an embodiment.

Referring to FIG. 2, the display device DD may include a display module DM and a window member WM. The display module DM may include a display panel DP, an input-sensing unit ISU, and an anti-reflector RPP.

The display panel DP may be a light-emitting display panel. For example, the display panel DP may be an organic light-emitting display panel, an inorganic light-emitting display panel, a micro LED display panel, or a nano LED display panel. The display panel DP may include a base layer BS, a circuit layer DP-CL, a light-emitting element layer DP-ED, and an encapsulation layer TFE.

The base layer BS may provide a base surface on which the circuit layer DP-CL is disposed. The base layer BS may be a rigid substrate or a flexible substrate that is bendable, foldable, rollable, and the like. The base layer BS may be a glass substrate, a metal substrate, a polymer substrate, or like. However, an embodiment of the inventive concept is not limited thereto, and the base layer BS may include an inorganic layer, an organic layer, or a composite material layer.

The base layer BS may have a multi-layered structure. For example, the base layer BS may include a first synthetic resin layer, a multi- or single-layered inorganic layer, or a second synthetic resin layer disposed on the multi- or single-layered inorganic layer. The first and second synthetic resin layers may each include a polyimide-based resin, and are not particularly limited.

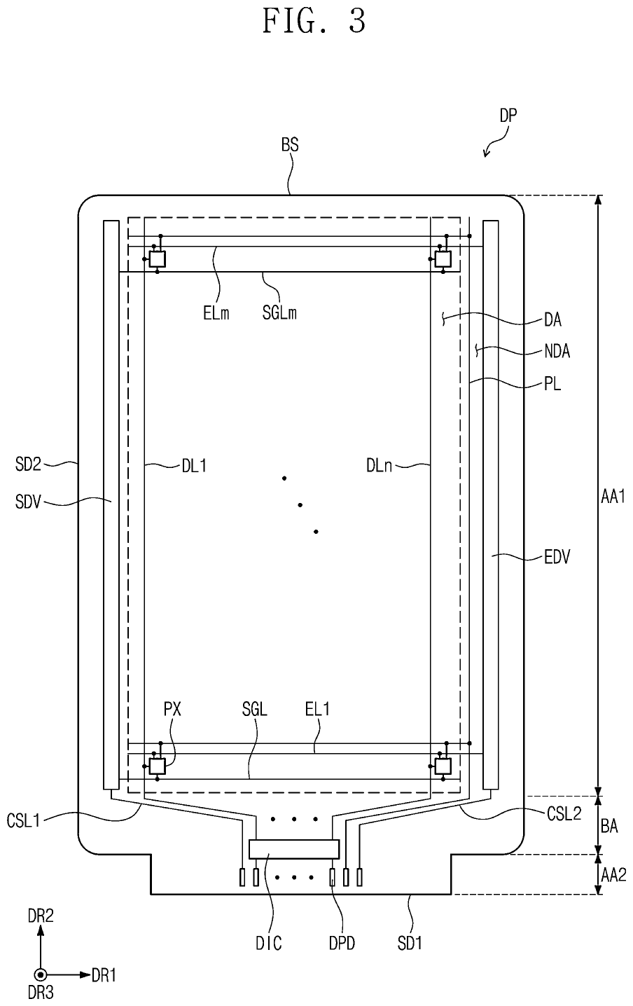

The circuit layer DP-CL may be disposed on the base layer BS. The circuit layer DP-CL may include an insulating layer, a semiconductor pattern, a conductive pattern, a signal line, and the like. The circuit layer DP-CL includes a driving circuit of a pixel PX to be described later (see FIG. 3).

The light-emitting element layer DP-ED may be disposed on the circuit layer DP-CL. The light-emitting element layer DP-ED may include a light-emitting element of the pixel PX to be described later (see FIG. 3). For example, the light-emitting element may include an organic light-emitting material, an inorganic light-emitting material, an organic-inorganic light-emitting material, quantum dots, quantum rods, a micro LED, or a nano LED.

The encapsulation layer TFE may be disposed on the light-emitting element layer DP-ED. The encapsulation layer TFE may protect the light-emitting element layer DP-ED against moisture, oxygen, and foreign substances such as dust particles. The encapsulation layer TFE may include at least one inorganic layer. The encapsulation layer TFE may include a stacked structure of an inorganic layer/an organic layer/an inorganic layer.

The input-sensing unit ISU may be disposed on the display panel DP. The input-sensing unit ISU may detect an external input applied from the outside. The external input may be a user's input. The user's input may include various types of external inputs such as a part of a user's body, light, heat, pen, or pressure.

The input-sensing unit ISU may be formed on the display panel DP through a continuous process. In this case, the input-sensing unit ISU may be directly disposed on the display panel DP. In this specification, the wording, “a B component being directly disposed on an A component” signifies that another component is not disposed between the A component and the B component. For example, an adhesive layer may not be disposed between the input-sensing unit ISU and the display panel DP.

The anti-reflector RPP may be disposed on the input-sensing unit ISU. The anti-reflector RPP may reduce reflectance for external light. The anti-reflector RPP may be directly disposed on the input-sensing unit ISU through a continuous process.

The anti-reflector RPP may include a light blocking pattern that overlaps a reflective structure disposed therebelow. The anti-reflector RPP may further include a color filter overlapping a light-emitting region to be described later. The color filter may include a first-color color filter, a second-color color filter, and a third-color color filter corresponding to a first-color pixel, a second-color pixel, and a third-color pixel.

The window member WM is disposed on the anti-reflector RPP. An adhesive layer AD may bond the window member WM and the anti-reflector RPP. The adhesive layer may be a pressure sensitive adhesive film (PSA) or an optically clear adhesive (OCA).

The window member WM includes at least one base layer. The base layer may be a glass substrate or a synthetic resin film. The window member WM may have a multi-layered structure. The window member WM may include a thin-film glass substrate and a synthetic resin film disposed on the thin-film glass substrate. The thin-film glass substrate and the synthetic resin film may be bonded via an adhesive layer, and the adhesive layer and the synthetic resin film may be separated from the thin-film glass substrate for replacement thereof.

In an embodiment, the adhesive layer AD may be omitted, and the window member WM may be directly disposed on the anti-reflector RPP. An organic material, an inorganic material, or a ceramic material may be applied on the anti-reflector RPP.

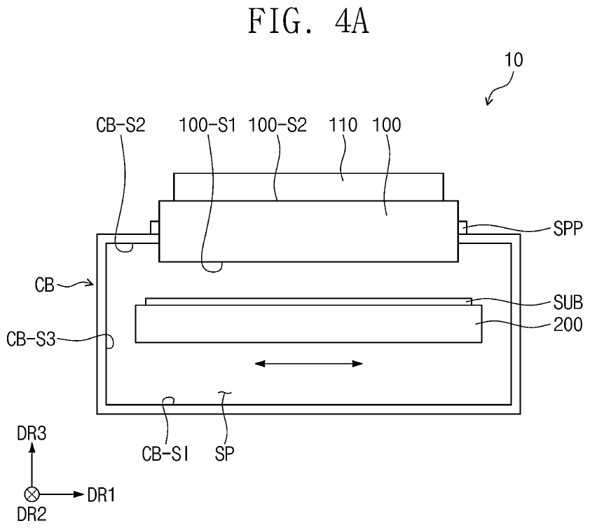

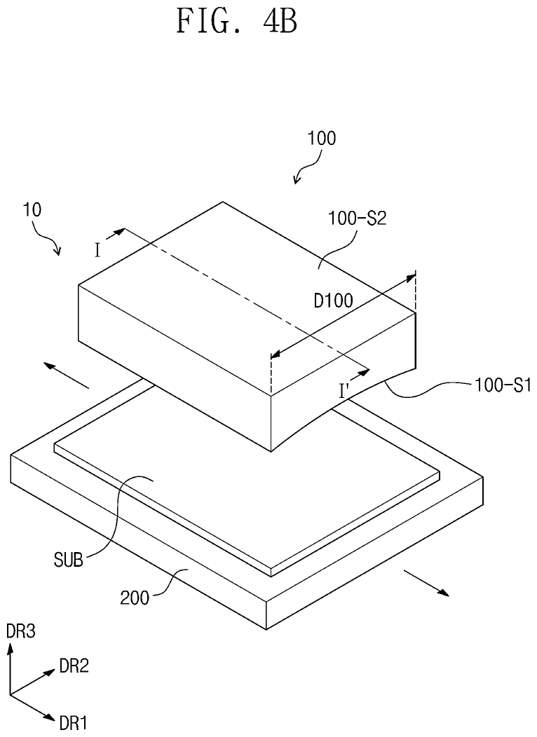

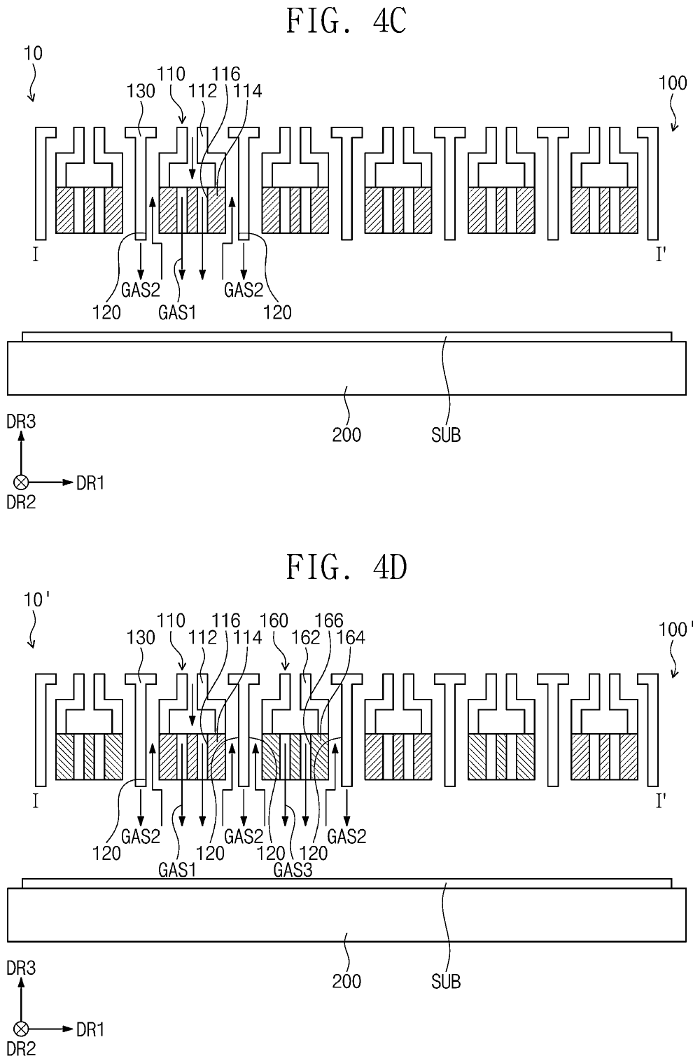

A deposition apparatus 10 to be described later (see FIG. 4A) may deposit a material onto a substrate SUB (see FIG. 4B). In this case, the substrate SUB (see FIG. 4B) may include the entirety or a portion of the base layer BS of the display panel DP but is not limited thereto. The substrate SUB may include the circuit layer DP-CL or the input-sensing unit ISU of the display module DM, and is not limited to any one embodiment.

FIG. 3 is a plan view of a display panel according to an embodiment.

For ease of description, FIG. 3 illustrates some components of the display panel DP in a block (or schematic) form. Referring to FIG. 3, the display panel DP may include a base layer 110 (see FIG. 2), a scan driving circuit SDV, an emission driving circuit EDV, a driver chip DIC, a plurality of panel signal lines SGL1 to SGLm, DL1 to DLn, EL1 to ELm, CSL1, CSL2, and PL, a plurality of pixels PX, and a plurality of display pads DPD.

The base layer 110 (see FIG. 2) includes a first base region AA1, a second base region AA2, and a bending region BA, which are separated in the second direction DR2. The second base region AA2 and the bending region BA may be a partial region of the non-display region NDA. The bending region BA is disposed between the first base region AA1 and the second base region AA2.

The first base region AA1 may be a region that includes the front surface IS of FIG. 1B. The second base region AA2 is spaced apart from the first base region AA1 with the bending region BA therebetween. The second base region AA2 and the bending region BA may each have a width smaller than that of the first base region AA1 in the first direction. That is, the length of each of the bending region BA and the second base region AA2 may be smaller than the length of the first base region AA1 in the first direction DR1.

A region having a shorter length in a bending axis direction may be bent more easily, as is illustrated in FIG. 3. The second base region AA2 and the bending region BA may have the same width as the first base region AA1 in the second direction DR2, and are not limited to any one embodiment.

The bending region BA is bent with respect to the bending axis extending along the first direction DR1. In a case that the bending region BA is not bent, the second base region AA2 may head in a direction the same as that of the first base region AA1; and in a case that the bending region BA is bent, the second base region AA2 may head in a direction opposed to that of the first base region AA1.

The above-described circuit board MB (see FIG. 1B) is physically connected to the second base region AA2. As the bending region BA is bent, the circuit board MB may be disposed on a rear surface of an electronic panel. Accordingly, a region defining the front surface IS becomes the first base region AA1, and the second base region AA2 and the bending region BA are invisible through the front surface IS. Therefore, a bezel region of an electronic device may be reduced.

The pixels PX each include a light-emitting element and a thin-film transistor connected thereto. A shape of the display panel DP illustrated in FIG. 3 is substantially the same as a planar shape of the above-described base layer. In this embodiment, the display region DA and the non-display region NDA may be distinguished according to whether a light-emitting element is therein.

FIG. 3 illustrates that the pixels PX are disposed in the display region DA. The display region DA may be a region in which the image IM is displayed, as is illustrated by way of example. Some components of the respective pixels PX may include thin-film transistors disposed in the non-display region NDA, and are not limited to any one embodiment.

The scan driving circuit SDV, the driver chip DIC, and the emission driving circuit EDV may be disposed in the non-display region NDA. The driver chip DIC may include a data driving circuit.

The panel signal lines SGL to SGLm, DL1 to DLn, EL1 to ELm, CSL1, CSL2, and PL may include a plurality of scan lines SGL to SGLm, a plurality of data lines DL1 to DLn, a plurality of emission lines EL1 to ELm, first and second control lines CSL1 and CSL2, and a power line PL. The data lines DL1 to DLn, the first and second control lines CSL1 and CSL2, and the power line PL among the panel signal lines SGL1 to SgLm, DL1 to DLn, EL1 to ELm, CSL1, CSL2, and PL may be respectively connected to the plurality of display pads DPD. Here, m and n are natural numbers. The pixels PX may be connected to the scan lines SGL1 to SGLm, the data lines DL1 to DLn, and the emission lines EL1 to Elm.

The scan lines SGL1 to SGLm may extend in the first direction DR1 to be connected to the scan driving circuit SDV. The data lines DL1 to DLn may extend in the second direction DR2 to be connected to the driver chip DIC via the bending region BA. The emission lines EL1 to ELm may extend in the first direction DR1 to be connected to the emission driving circuit EDV.

The power line PL may include a portion extending in the second direction DR2 and a portion extending in the first direction DR1. The portion extending in the first direction DR1 and the portion extending in the second direction DR2 may be disposed on different layers. A portion, of the power line PL, extending in the second direction DR2 may extend to the second base region AA2 via the bending region BA. The power line PL may provide a first voltage to the pixels PX.

The first control line CSL1 may be connected to the scan driving circuit SDV, and extend toward a lower end of the second base region AA2 via the bending region BA. The second control line CSL2 may be connected to the emission driving circuit EDV, and extend toward the lower end of the second base region AA2 via the bending region BA.

When viewed from the top (i.e., a plan view), the display pads DPD may be disposed adjacent to the lower end of the second base region AA2. The driver chip DIC, the power line PL, the first control line CSL1, and the second control line CSL2 may be connected to the display pads DPD. The circuit board MB may be electrically connected to the display pads DPD via an anisotropic conductive adhesive layer.

The display panel DP and the input-sensing unit ISU (see FIG. 2) may each include a first side SD1 extending in the first direction DR1 and a second side SD2 extending in the second direction DR2. In this embodiment, the first side SD1 may be a side to which the display pads DPD and the sensing pads PD are disposed adjacent, and the second side SD2 may be a side that is adjacent to the first side SD1 and extends from the first side SD1 in the second direction DR2.

FIG. 4A is a front view schematically illustrating a deposition apparatus according to an embodiment, and FIG. 4B is a perspective view of a part of a deposition apparatus according to an embodiment.

Referring to FIGS. 4A and 4B, a deposition apparatus 10 according to an embodiment may include a deposition chamber CB, a gas spraying part 100, and a substrate conveying part 200.

The deposition chamber CB may include an inner space SP. The substrate SUB, the gas spraying part 100, and the substrate conveying part 200 may be accommodated in the inner space SP of the deposition chamber CB. The inner space SP may provide a vacuum state or a non-vacuum state to a substrate.

The inner space SP may be defined by a floor surface CB-S1, a ceiling surface CB-S2, and a wall surface CB-S3 of the deposition chamber CB. The floor surface CB-S1 may be defined by the first direction DR1 and the second direction DR2 crossing each other. The ceiling surface CB-S2 may be opposed to the floor surface CB-S1. The wall surface CB-S3 may connect the floor surface CB-S1 and the ceiling surface CB-S2.

The deposition chamber CB may include a support part SPP supporting the gas spraying part 100 to be described later. The support part SPP may support the gas spraying part 100 in a direction that is farther away from the substrate SUB or in the third direction DR3. According to an embodiment, the support part SPP may support a part of an end of the gas spraying part 100, but is not limited thereto. The support part SPP may support the entirety of the end of the gas spraying part 100, and is not limited to any one embodiment.

The substrate SUB may include the base layer 110 (see FIG. 2) of the display panel DP described above (see FIG. 2) and is not limited thereto. The substrate SUB may include the circuit layer 120 (see FIG. 2) or the input sensor ISU (see FIG. 2) of the display module DM (see FIG. 2).

The substrate conveying part 200 may be accommodated in the inner space SP of the deposition chamber CB. The substrate conveying part 200 may support the substrate SUB onto which deposition is to be performed. The substrate conveying part 200 may convey the substrate SUB in the deposition chamber CB. The substrate conveying part 200 may reciprocally convey the substrate SUB under the gas spraying part 100 along the first direction DR1.

The gas spraying part 100 may be accommodated in the inner space SP of the deposition chamber CB. The gas spraying part 100 may include a lower surface 100-S1 and an upper surface 100-S2. The lower surface 100-S1 may face the substrate SUB, and the upper surface 100-S2 may be opposed to the lower surface 100-S1.

The gas spraying part 100 may spray gas onto the substrate SUB. The gas spraying part 100 may form a thin film on the substrate SUB by spraying a process gas toward the substrate SUB which is being reciprocally conveyed under the gas spraying part 100 in the first direction DR1. The deposition apparatus 10 according to one embodiment may be used for various deposition processes according to a type of process gas sprayed on the substrate, a spraying method, and whether to apply a high voltage. For example, the deposition apparatus 10 may be used in various deposition processes such as an atomic layer deposition (ALD) process, a plasma enhanced atomic layer deposition (PEALD) process, a chemical vapor deposition (CVD) process, and a plasma enhanced chemical vapor deposition (PECVD) process. For example, in a case that the deposition apparatus 10 is used in the ALD process or the PEALD process, nozzles included in the gas spraying part 100 may each spray a source gas and a process gas. In a case that the deposition apparatus 10 is applied in the CVD process or the PECVD process, nozzles may each spray mixed gas.

According to an embodiment, a length D100 of the gas spraying part 100 in the second direction DR2 may be a predetermined length or more. The length D100 of the gas spraying part 100 in the second direction DR2 may correspond to the length of the substrate SUB. That is, as a size of the substrate SUB increases, the length D100 of the gas spraying part 100 in the second direction DR2 may also increase.

For example, the length D100 of the gas spraying part 100 in the second direction DR2 may be about 2400 mm or more. The length D100 of the gas spraying part 100 in the second direction DR2 may be about 2400 mm or more, and thus a center portion of the gas spraying part 100 may sag toward the substrate SUB in the deposition chamber CB the inner space SP of which is in the vacuum state. In this case, both side portions of the gas spraying part 100 may also sag together, but the degrees of sagging of the both side portions of the gas spraying part 100 may be less than the degree of sagging of the center portion of the gas spraying part 100. In this case, the non-vacuum state may be defined as a normal pressure state.

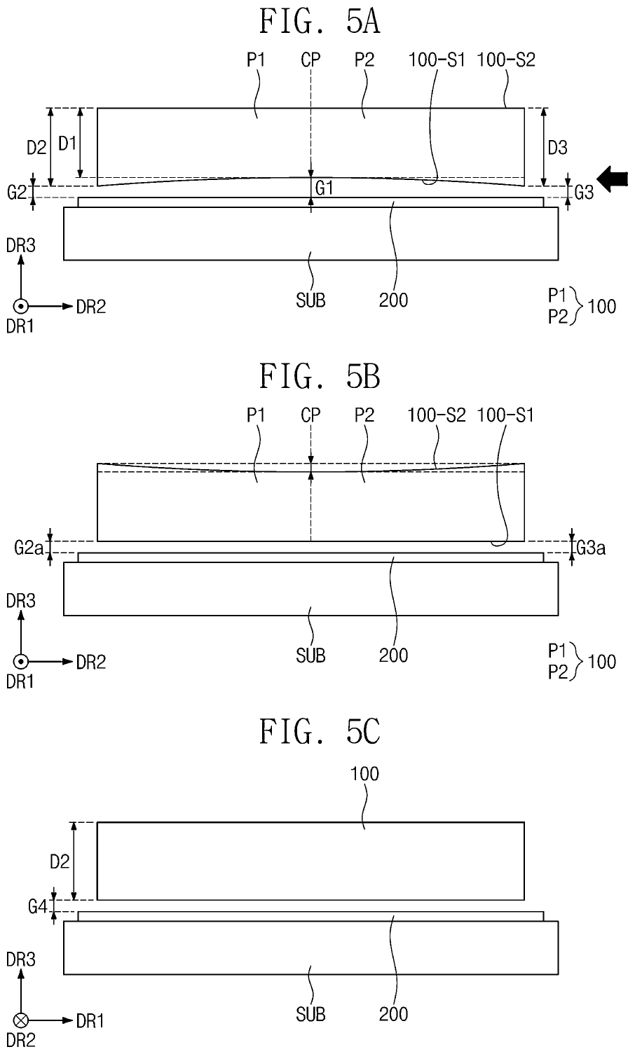

In the non-vacuum state, that is, the normal pressure state, the gas spraying part 100 may not sag toward the substrate SUB. Accordingly, the lower surface 100-S1 of the gas spraying part 100 is made to be recessed toward the substrate SUB in the non-vacuum state, and then, in the vacuum state, the center portion of the gas spraying part 100 is sagged toward the substrate SUB, so that a gap between the lower surface 100-S1 of the gas spraying part 100 and the upper surface of the substrate SUB is maintained constant in the vacuum state. The detailed description thereof will be described later with reference to FIGS. 5A to 5C.

FIGS. 4C and 4D are cross-sectional views schematically illustrating a deposition apparatus according to an embodiment.

Referring to FIG. 4C, the gas spraying part 100 may include a plurality of first nozzle portions 110 and discharging portions 120.

The first nozzle portions 110 may be aligned along the first direction DR1. In the drawings, the first nozzle portions 110 and the discharging portions 120 are illustrated to extend in the second direction DR2 but are not limited thereto. The first nozzle portions 110 and the discharging portions 120 may extend in a direction crossing the second direction DR2, and are not limited to any one embodiment.

In the drawings, six first nozzle portions 110 are illustrated, but the number of the first nozzle portions 110 is not limited thereto. Five or less or seven or more first nozzle portions 110 may be disposed.

The first nozzle portions 110 may each spray a first process gas GAS1 onto the substrate SUB so as to form a thin film on the substrate SUB. In an embodiment, the first nozzle portions 110 may respectively spray different first process gases GAS1 onto the substrate SUB, and without being limited thereto, some of the first nozzle portions 110 may spray the same first process gas GAS1 onto the substrate SUB.

The respective discharging portions 120 may be disposed around the first nozzle portions 110. The discharging portions 120 may be connected to a discharging pump, etc., and discharge, to the outside, by-products or excess process gases separated from the substrate SUB. The discharging portions 120 may prevent the first process gas GAS1, sprayed from the respective first nozzle portions 110, from moving toward another first nozzle portion 110 adjacent thereto. For example, the discharging portions 120 may be disposed to respectively surround the first nozzle portions 110 on a plane, but is not limited thereto.

The deposition apparatus 10 may further include a plurality of curtain gas spraying parts 130. The curtain gas spraying parts 130 may be respectively disposed around the first nozzle portions 110 and spray curtain gas GAS2 toward the substrate SUB. The curtain gas GAS2 may be nonreactive to the first process gas GAS1 sprayed from the first nozzle portions 110. For example, the curtain gas GAS2 may be an inert gas such as argon (Ar) gas and nitrogen (N2) gas, and is not limited to any one embodiment.

For example, the curtain gas spraying parts 130 may be disposed to respectively surround the first nozzle portions 110 on a plane. The curtain gas GAS2, which is sprayed from each of the curtain gas spraying parts 130, may serve as a curtain which surrounds each of the first nozzle portions 110 so as to keep the first process gas GAS1, which is sprayed from the first nozzle portions 110, from being dispersed into the surroundings and mixed with another process gas. Therefore, even in a case that the first nozzle portions 110 respectively spray different process gases GAS1 onto the substrate SUB at the same time, the process gases GAS1 may not be mixed.

The first nozzle portion 110 may each include a first gas supplying portion 112 and a first electrode 114.

The first gas supplying portion 112 may supply the first process gas GAS1. For example, the first gas supplying portion 112 may transmit the first process gas GAS1 supplied from the outside to the substrate SUB via the first electrode 114.

The first electrode 114 may be disposed under the first gas supplying portion 112. The first process gas GAS1 may be sprayed onto the substrate SUB via the first electrode 114.

A first nozzle 116 may be formed inside the first electrode 114. Referring to the drawing, the first nozzle 116 may be formed to pass through the first electrode 114 in the thickness direction, that is, the third direction DR3. However, an embodiment of the inventive concept is not limited thereto. The first nozzle 116 may be formed to pass through the first electrode 114 in one direction crossing the third direction DR3, and is not limited to any one embodiment.

According to an embodiment, the first electrode 114 selectively converts the first process gas GAS1, supplied from the first gas supplying portion 112, into a plasma state and then the gas in the plasma state may be sprayed onto the substrate SUB.

FIG. 4D illustrates another embodiment of the nozzle portion illustrated in FIG. 4C. The same reference numerals or symbols are used for the components duplicated with those described above, and a detailed description thereof will be omitted for sake of brevity.

Referring to FIG. 4D, a nozzle portion 100′ may include a first nozzle portion 110, a second nozzle portion 160, and a discharging portion 120.

As illustrated in the drawing, the first nozzle portion 110 and the second nozzle portion 160 may be aligned along the second direction DR2. The first nozzle portion 110 and the second nozzle portion 160 may be alternately arranged along the first direction DR1. The first nozzle portion 110 and the second nozzle portion 160 may each extend in the second direction DR2, but are not limited thereto.

A second process gas GAS3, which is sprayed from the second nozzle portion 160, may include a different material from that of the first process gas GAS1 which is sprayed from the first nozzle portion 110, but is not limited thereto.

The first nozzle portion 110 may include the first gas supplying portion 112 and the first electrode 114, and the second nozzle portion 160 may include a second gas supplying portion 162 and a second electrode 164. The second gas supplying portion 162 may substantially perform the same function as the above-described first gas supplying portion 112. Also, the second electrode 164 may perform the substantially same function as the above-described first electrode 114.

The configurations of the gas spraying parts 100 and 100′, described in FIGS. 4C and 4D are illustrated as examples of the gas spraying parts 100 and 100′ which are applied to this apparatus, and are not limited to the configuration described in the drawings and the description above.

FIGS. 5A to 5C are cross-sectional views of the deposition apparatus 10 according to an embodiment (see FIG. 4A). Specifically, FIG. 5A is a cross-sectional view of the deposition apparatus 10, in the non-vacuum state, according to an embodiment (see FIG. 4A), when viewed in the first direction DR1, FIG. 5B is a cross-sectional view of the deposition apparatus 10, in the vacuum state, according to an embodiment (see FIG. 4A), when viewed in the first direction DR1, and FIG. 5C is a cross-sectional view of the deposition apparatus 10 according to an embodiment (see FIG. 4A), when viewed in the second direction DR2.

Referring to FIG. 5A, in the non-vacuum state, a lower surface 100-S1 of the gas spraying part 100 of the deposition apparatus 10 (see FIG. 4A) may have a curved surface. In the non-vacuum state, the lower surface 100-S1 of the gas spraying part 100 of the deposition apparatus 10 (see FIG. 4A) may have a recessed surface with respect to the substrate SUB. In the non-vacuum state, the lower surface 100-S1 of the gas spraying part 100 has a recessed surface with respect to the substrate SUB, and it is thus possible to prevent the lower surface 100-S1 of the gas spraying part 100 from contacting an upper surface of the substrate SUB even in a case that the gas spraying part 100 sags toward the substrate SUB in the vacuum state.

In the non-vacuum state, an upper surface 100-S2 of the gas spraying part 100 may have a flat surface. Specifically, the upper surface 100-S2 of the gas spraying part 100 may have a flat surface on a plane defined by the first direction DR1 and the second direction DR2. However, as will be described later, as long as a gap between the lower surface 100-S1 of the gas spraying part 100 and the upper surface of the substrate SUB may be maintained constant in the vacuum state, the lower surface 100-S1 of the gas spraying part 100 may have a curved surface without being limited to the description above. However, the disclosure is not limited to any one embodiment.

The gas spraying part 100 may include a first portion P1 and a second portion P2. The first portion P1 and the second portion P2 may be connected to each other with a center portion CP of the gas spraying part 100 as a boundary. That is, the first portion P1 may be located on one side with respect to the center portion CP of the gas spraying part 100, and the second portion P2 may be located on the other side of the center portion CP of the gas spraying part 100. The first portion P1 and the second portion P2 may be symmetrical to each other with respect to the center portion CP of the gas spraying part 100, but may be different from each other without being limited thereto. However, the disclosure is not limited to any one embodiment.

According to an embodiment, a thickness of the gas spraying part 100 may vary along the second direction DR2. That is, thicknesses of some portions of the gas spraying part 100 may be different from each other along the second direction DR2. That is, a first thickness D1 of the center portion CP of the gas spraying part 100 may be different from a second thickness D2 of the first portion P1 and a third thickness D3 of the second portion P2. A difference, between the second thickness D2 of the first portion P1 or the third thickness D3 of the second portion P2 and the first thickness D1 of the center portion CP of the gas spraying part 100, may correspond to a degree of sagging of the center portion CP of the gas spraying part 100.

Specifically, the difference, between the second thickness D2 of the first portion P1 and the first thickness D1 of the center portion CP of the gas spraying part 100, may be a value in the range from about 0.1 mm to about 1 mm. Also, the difference, between the third thickness D3 of the second portion P2 and the first thickness D1 of the center portion CP of the gas spraying part 100, may be a value in the range from about 0.1 mm to about 1 mm.

According to an embodiment, the first portion P1 and the second portion P2 of the gas spraying part 100 may be symmetrical to each other with respect to the center portion CP of the gas spraying part 100. Accordingly, the second thickness D2 of the first portion P1 and the third thickness D3 of the second portion P2, which are described above, may be the same.

According to an embodiment, a distance between the gas spraying part 100 and the substrate SUB may become smaller as getting farther away from the center portion CP of the substrate SUB. A distance, between the substrate SUB and the center portion CP of the lower surface 100-S1 of the gas spraying part 100, may be defined as a first gap G1, and distances, between the substrate SUB and one side and the other side portions of the lower surface 100-S1 of the gas spraying part 100, may be respectively defined as a second gap G2 and a third gap G3. That is, a gap between the substrate SUB and the center portion CP of the gas spraying part 100 may be defined as the first gap G1, a gap between the substrate SUB and the first portion P1 of the gas spraying part 100 may be defined as the second gap G2, and a gap between the substrate SUB and the second portion P2 of the gas spraying part 100 may be defined as the third gap G3.

In the non-vacuum state, the first gap G1 may be greater than the second gap G2 and the third gap G3. That is, since in the non-vacuum state, the lower surface 100-S1 of the gas spraying part 100 has a recessed surface with respect to the substrate SUB, the first gap G1 may be greater than the second gap G2 and the third gap G3.

According to an embodiment, the second gap G2 and the third gap G3 may be the same. The second gap G2 and the third gap G3 may be symmetrical to each other with respect to the center portion CP of the lower surface 100-S1 of the gas spraying part 100.

According to an embodiment, the second gap G2 and the third gap G3 may each be a value in the range from about 0.3 mm to about 2 mm in the non-vacuum state, and a difference between the second gap G2 and the first gap G1 in the non-vacuum state may be a value in the range from about 0.1 mm to about 1 mm.

The second gap G2 and the third gap G3 are each about 0.3 mm or more, and it is thus possible to prevent the gas spraying part 100 from contacting the substrate SUB even in a case that the gas spraying part 100 sags in the vacuum state. The second gap G2 and the third gap G3 are each a value in the range from about 2 mm or less, and it is thus possible to minimize a pressure deviation of the nozzles between the gas spraying part 100 and the substrate SUB. That is, the second gap G2 and the third gap G3 are each a value in the range from about 2 mm or less, and it is thus possible to easily control a gas flow and plasma distribution between the gas spraying part 100 and the substrate SUB.

Alternatively, the second gap G2 and the third gap G3 may each be a value in the range from about 0.6 mm to about 1 mm. The second gap G2 and the third gap G3 are each a value in the range from about 0.6 mm or more, and it is thus possible to prevent the gas spraying part 100 from contacting the substrate SUB even in a case that the gas spraying part 100 becomes larger and sags in the vacuum state.

The difference between the second gap G2 and the first gap G1 is a value in the range from about 0.1 mm or more, and it is thus possible to prevent the center portion CP of the gas spraying part 100 from contacting the substrate SUB even in a case that the center portion CP of the gas spraying part 100 sags further than both side portions thereof in the vacuum state.

The difference between the second gap G2 and the first gap G1 is a value in the range from about 1 mm or less, and it is thus possible to reduce a deviation of a gap between the substrate SUB and the center portion CP of the gas spraying part 100, and gaps between the substrate SUB and the both side portions of the gas spraying part 100, in the vacuum state, even in a case that the center portion CP sags in the vacuum state.

The deviation of the gaps G1, G2, and G3 in the vacuum state may be reduced, thereby minimizing a deviation of gas flow, between the substrate SUB and the center portion CP of the gas spraying part 100, and gas flow, between the substrate SUB and the both side portions of the gas spraying part 100. During the process of generating plasma, it is possible to minimize a deviation of a plasma density, between the substrate SUB and the center portion CP of the gas spraying part 100, and plasma densities between the substrate SUB and the both side portions of the gas spraying part 100.

Referring to FIG. 5B, in the vacuum state, the upper surface 100-S2 of the gas spraying part 100 of the deposition apparatus 10 (see FIG. 4A) may have a curved surface. In the vacuum state, the lower surface 100-S1 of the gas spraying part 100 may have a flat surface. Specifically, the lower surface 100-S1 of the gas spraying part 100 may have a flat surface on a plane defined by the first direction DR1 and the second direction DR2. In this case, a gap between the lower surface 100-S1 of the gas spraying part 100 and the upper surface 100-S2 of the substrate SUB may be constant.

That is, in the non-vacuum state, the first gap G1 (see FIG. 5A) between the substrate SUB and the center portion CP of the gas spraying part 100 is different from the second gap G2 (see FIG. 5A) or the third gap G3 (see FIG. 5A) between the substrate SUB and either side of the gas spraying part 100, while in the vacuum state, the gap between the substrate SUB and the center portion CP of the gas spraying part 100 may be the same as a second gap G2a or a third gap G3a between the substrate SUB and either side of the gas spraying part 100. In the vacuum state, the gap between the substrate SUB and the center portion CP of the gas spraying part 100 is made to be equal to the second gap G2a, and it is thus possible to minimize a deviation between gas flow between the substrate SUB and the center portion CP of the gas spraying part 100, and gas flow between the substrate SUB and the both side portions of the gas spraying part 100. During the process of generating plasma, it is possible to minimize a deviation of a plasma density, between the substrate SUB and the center portion CP of the gas spraying part 100, and plasma densities between the substrate SUB and the both side portions of the gas spraying part 100.

Referring to FIG. 5C, a thickness of the gas spraying part 100 as viewed in the second direction DR2 is constant along the first direction DR1. The first portion P1 and the second portion P2 of the gas spraying part 100 may each be located in the second direction DR2 with respect to the center portion CP of the gas spraying part 100. As described above, the first portion P1 and the second portion P2 of the gas spraying part 100 may be symmetrical to each other with respect to the center portion CP of the gas spraying part 100, the second thickness D2 of the first portion P1 and the third thickness D3 of the second portion P2 may be the same as the second thickness D2, and a gap between the gas spraying part 100 and the substrate SUB may be the same as the second gap G2 (see FIG. 5A) or the third gap G3 (see FIG. 5A), which has been described above.

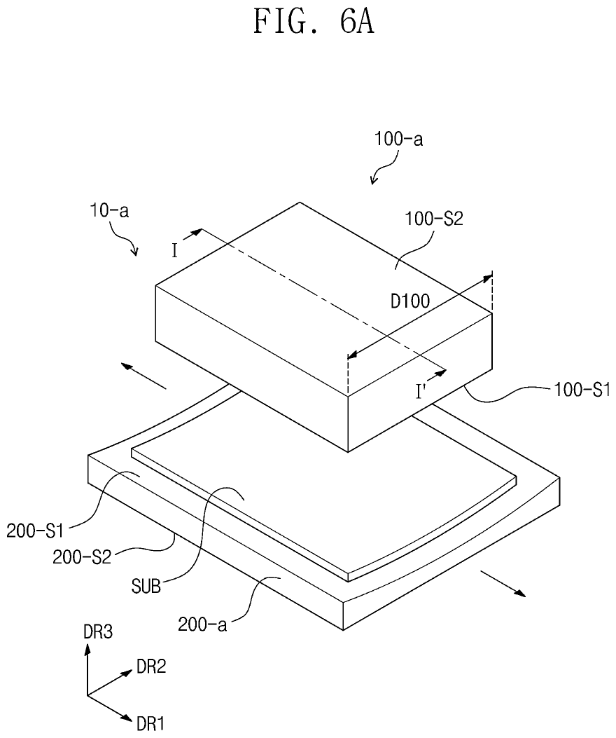

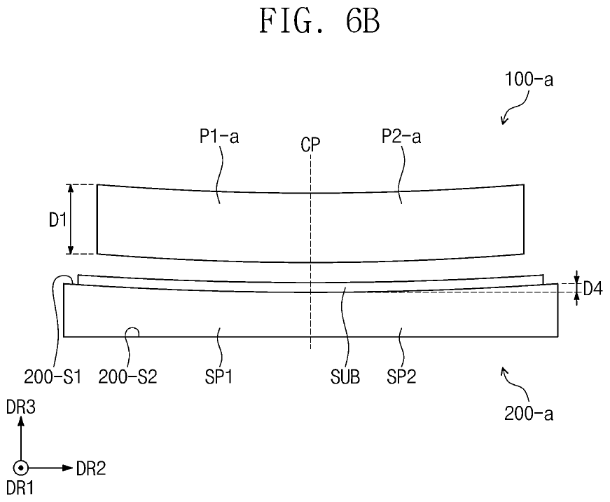

FIG. 6A is a perspective view of a part of a deposition apparatus 10-a according to an embodiment, and FIG. 6B is a cross-sectional view of the deposition apparatus 10-a, in a vacuum state, according to an embodiment Specifically, FIG. 6A illustrates another embodiment different with the deposition apparatus 10 (see FIG. 4A) according to an embodiment, illustrated in FIG. 4A, and FIG. 6B is a cross-sectional view of the deposition apparatus 10-a illustrated in FIG. 6A in the vacuum state, when viewed in the first direction DR1. The same reference numerals or symbols are used for the components same as those described above with the references to FIGS. 4A to 5C, and a detailed description thereof will be omitted for sake of brevity.

Referring to FIGS. 6A and 6B, the deposition apparatus 10-a may include a gas spraying part 100-a and a substrate conveying part 200-a. Unlike an embodiment of the deposition apparatus 10 (see FIG. 4A) illustrated in FIG. 4B, a thickness of the gas spraying part 100-a of the deposition apparatus 10-a, according to an embodiment, illustrated in FIG. 6A may be constant along the second direction DR2.

Also, in a non-vacuum state, an upper surface 100-S2 and a lower surface 100-S1 of the gas spraying part 100-a may have a flat surface. In the vacuum state, the gas spraying part 100-a may sag, and the upper surface 100-S2 and the lower surface 100-S1 of the gas spraying part 100-a may have a recessed surface with respect to the substrate SUB.

A substrate conveying part 200-a may include an upper surface 200-S1 and a lower surface 200-S2. According to an embodiment, the upper surface 200-S1 of the substrate conveying part 200-a may be a recessed surface with respect to the substrate SUB. In this case, the upper surface 200-S1 of the substrate conveying part 200-a may be a recessed surface with respect to the substrate SUB in the vacuum state and the non-vacuum state.

The substrate conveying part 200-a may include a first support portion SP1 and a second support portion SP2. The first support portion SP1 and the second support portion SP2 may be connected to each other with a center portion of the substrate conveying part 200-a as a boundary. That is, the first support portion SP1 may be located on one side with respect to the center portion of the substrate conveying part 200-a, and the second support portion SP2 may be located on the other side of the center portion of the substrate conveying part 200-a. In this case, the center portion of the substrate conveying part 200-a may correspond to the center portion CP of the gas spraying part 100-a. According to an embodiment, the first support portion SP1 and the second support portion SP2 may be symmetrical to each other with respect to the center portion of the substrate conveying part 200-a.

The first support portion SP1 may overlap a first portion P1-a of the gas spraying part 100-a, and the second support portion SP2 may overlap a second portion P2-a of the gas spraying part 100-a.

The first support portion SP1 and the second support portion SP2 may become further recessed as being closer to the center portion of the substrate conveying part 200-a. Referring to the drawings, the first support portion SP1 may be further recessed in a direction being closer to the second support portion SP2 and have a curved surface. The second support portion SP2 may be further recessed in a direction being closer to the first support portion SP1 in the second direction DR2 and have a curved surface.

According to an embodiment, a difference between a thickness of a terminal of the first support portion SP1 or the second support portion SP2 in the third direction DR3 and a thickness of the center portion CP of the substrate conveying part 200-a may correspond to a degree of sagging of the center portion CP of the gas spraying part 100-a. A difference between a thickness of a terminal of the first support portion SP1 or the second support portion SP2 in the third direction DR3 and a thickness D4 of the center portion of the substrate conveying part 200-a may correspond to a degree of sagging of the first portion P1-a or the second portion P2-a of the gas spraying part 100-a in the third direction DR3. The difference, between a thickness of the terminal of the first support portion SP1 or the second support portion SP2 and a thickness of the center portion of the substrate conveying part 200-a, may be a value in the range from about 0.1 mm to about 1 mm.

The upper surface of the substrate conveying part 200-a is made to be recessed with respect to the substrate SUB, and it is thus possible to make the substrate SUB partially sag over the conveying part 200-a. Since the substrate SUB is made to partially sag, it is possible to prevent the substrate SUB from contacting the gas spraying part 100-a even in a case that the gas spraying part 100-a sags toward the substrate in the vacuum state.

A deposition apparatus according to an embodiment may prevent a gas spraying part from contacting a substrate in a vacuum state.

A deposition device according to an embodiment may easily control a gas flow between a gas spraying part and a substrate.

A deposition device according to an embodiment may allow plasma to have a uniform density according to a position between a gas spraying part and a substrate.

Although various embodiments have been described, it is understood that the invention should not be limited to these embodiments but various changes and modifications can be made by one ordinary skilled in the art within the spirit and scope of the invention as hereinafter claimed. Therefore, the spirit and scope of the invention is not limited to the contents described in the detailed description of the specification, but should be determined by the claims.

What is claimed is:

1. A deposition apparatus comprising:
a deposition chamber including an inner space that accommodates a substrate and provides a vacuum state or a non-vacuum state to the substrate, the inner space being defined by a floor surface defined by a first direction and a second direction crossing each other, a ceiling surface opposed to the floor surface, and a wall surface connecting the floor surface and the ceiling surface;
a gas spraying part that is accommodated in the inner space, which includes a lower surface facing the substrate and an upper surface opposed to the lower surface, and which sprays gas onto the substrate; and
a substrate conveying part accommodated in the inner space, having the substrate disposed thereon, and which moves the substrate in the first direction, wherein
a thickness of the gas spraying part varies along the second direction, and
in the non-vacuum state, the lower surface of the gas spraying part has a curved surface, and in the vacuum state, the lower surface of the gas spraying part has a flat surface on a plane defined by the first direction and the second direction.

2. The deposition apparatus of claim 1, wherein
in the non-vacuum state, the upper surface of the gas spraying part has a flat surface defined by the first direction and the second direction, and
in the vacuum state, the upper surface of the gas spraying part has a curved surface.

3. The deposition apparatus of claim 2, wherein in the non-vacuum state, the lower surface is a recessed surface with respect to the substrate.

4. The deposition apparatus of claim 1, wherein
the gas spraying part has a first thickness at a center portion of the gas spraying part, and respectively have a second thickness and a third thickness at one side portion and another side portion of the gas spraying part, and
the second thickness and the third thickness are symmetrical with respect to the center portion of the gas spraying part.

5. The deposition apparatus of claim 4, wherein a difference between the second thickness and the first thickness is a value in a range from about 0.1 mm to about 1 mm.

6. The deposition apparatus of claim 1, wherein in the non-vacuum state, a first gap defined as a distance between a center portion of the lower surface and the substrate is greater than a second gap and a third gap defined as distances between the substrate and one side and the other side portions of the lower surface.

7. The deposition apparatus of claim 6, wherein the second gap and the third gap are symmetrical with respect to the center portion of the lower surface.

8. The deposition apparatus of claim 6, wherein
the second gap and the third gap are each a value in a range from about 0.3 mm to about 2 mm, and
a difference between the second gap and the first gap is a value in a range from about 0.1 mm to about 1 mm.

9. The deposition apparatus of claim 8, wherein the second gap and the third gap are each a value in a range from about 0.6 mm to about 1 mm.

10. The deposition apparatus of claim 1, wherein the gas spraying part has a length of about 2400 mm or more in the second direction.

11. The deposition apparatus of claim 1, wherein
the gas spraying part is provided in plurality, and
the plurality of gas spraying parts comprise a first gas spraying part that sprays first gas, and a second gas spraying part that sprays second gas different from the first gas.

12. The deposition apparatus of claim 1, wherein the deposition chamber further comprises a support part that supports the gas spraying part.

13. A deposition apparatus comprising:
a deposition chamber including an inner space that accommodates a substrate and provides a vacuum state or a non-vacuum state to the substrate, the inner space being defined by a floor surface defined by a first direction and a second direction crossing each other, a ceiling surface opposed to the floor surface, and a wall surface connecting the floor surface and the ceiling surface;
a gas spraying part that is accommodated in the inner space, which includes a lower surface facing the substrate and an upper surface opposed to the lower surface, and which sprays gas onto the substrate; and
a substrate conveying part accommodated in the inner space, having the substrate disposed thereon, and which moves the substrate in the first direction, wherein
the gas spraying part is disposed along the second direction crossing the first direction, and includes a first portion and a second portion connected to each other with a center portion thereof as a boundary,
in the non-vacuum state, a first gap defined as a distance between the center portion and the substrate is greater than a second gap defined as a distance between the first portion and the substrate, and
in the vacuum state, the first gap is same as the second gap.

14. The deposition apparatus of claim 13, wherein
in the non-vacuum state, a third gap defined by a distance between the second portion and the substrate is smaller than the first gap, and
the second gap and the third gap are symmetrical with respect to the center portion.

15. The deposition apparatus of claim 13, wherein the deposition chamber further comprises a support part which supports the gas spraying part.

16. The deposition apparatus of claim 13, wherein
the center portion has a first thickness between the lower surface and the upper surface,
the first portion has a second thickness greater than the first thickness between the lower surface and the upper surface,
the second portion has a third thickness greater than the first thickness between the lower surface and the upper surface, and
the second thickness and the third thickness are symmetrical with respect to the center portion.

17. The deposition apparatus of claim 16, wherein
the first gap is a value in a range from about 0.3 mm to about 2 mm, and
a difference between the second gap and the first gap is a value in a range from about 0.1 mm to about 1 mm.

18. The deposition apparatus of claim 16, wherein a difference between the second thickness and the first thickness is a value in a range from about 0.1 mm to about 1 mm.

19. The deposition apparatus of claim 13, wherein an upper surface of the substrate conveying part is a recessed surface with respect to the substrate.

20. The deposition apparatus of claim 19, wherein the substrate conveying part comprises:
a first support portion overlapping the first portion; and
a second support portion overlapping the second portion, the first support portion and the second support portion connected to each other with a center portion, of the substrate conveying part, corresponding to the center portion of the gas spraying part as a boundary, and
the first support portion and the second support portion become further recessed as being closer to the center portion of the substrate conveying part.
